(19) United States
(12) Patent Application Publication
(10) Pub. No.: US 2020/0303571 A1
(43) Pub. Date: Sep. 24, 2020

(54) I-III-VI2 PHOTOVOLTAIC ABSORBER LAYERS

(71) Applicant: UNIVERSITY OF DELAWARE, Newark, DE (US)

(72) Inventors: Gregory M. Hanket, Newark, DE (US); William N. Shafarman, Wilmington, DE (US)

(21) Appl. No.: 16/868,002

(22) Filed: May 6, 2020

Related U.S. Application Data
(62) Division of application No. 12/244,309, filed on Oct. 2, 2008.
(60) Provisional application No. 60/997,289, filed on Oct. 2, 2007.

(51) Int. Cl. H01L 31/032; H01L 31/0392

(52) U.S. Cl. CPC H01L 31/0322; H01L 31/0392; Y02P 70/521; Y02E 10/541; H01L 31/03923

(57) ABSTRACT

The invention provides a film having a composition Ag_{w}Cu_{1-w}InᵣGaₓKySe_{2(1-z)}Q_{2z}; wherein K is Al or Tl or a combination of these; Q is S or Te or a combination of these; w is in a range from 0.01 to 0.75; x is in a range from 0.1 to 0.8; and r, y and z are each independently in a range from 0 to 1, provided that r+x+y=1. Methods of making the film can include processing temperatures not exceeding 500° C.

### CROSS REFERENCE TO RELATED APPLICATIONS

This patent application is a divisional of U.S. patent application Ser. No. 12/244,309, filed Oct. 2, 2008, which claims priority benefit of U.S. Provisional Pat. Appln. No. 60/997,289, filed Oct. 2, 2007, the entirety of which is incorporated herein by reference.

### STATEMENT REGARDING FEDERALLY SPONSORED RESEARCH

The U.S. Government has a paid-up license in this invention and the right in limited circumstances to require the patent owner to license others on reasonable terms as provided for by the terms of Contract No. ADJ-1-30630-12, awarded by the U.S. Department of Energy.

### BACKGROUND OF THE INVENTION

I-III-VI₂ alloys, in particular CuInSe₂-based alloys, are well known for use in making photovoltaic thin film absorber layers. Such alloys may incorporate elements such as Ga or Al to partially or wholly substitute for In and S to partially or wholly substituted for Se. The partial substitution of Ga for In, and S for Se, improves photovoltaic conversion efficiency in part by increasing the bandgap to more efficiently utilize incoming sunlight. The substitution of Al for In has also been shown to improve device efficiency, but Al incorporation is not commonly practiced due to a variety of difficulties encountered in processing.

Unfortunately, the modification of CuInSe₂ with other elements to maximize photovoltaic performance in many cases increases the melting and annealing temperatures of the compositions, requiring processing temperatures in excess of 500° C. and often as high as 525° C.-600° C. The need to use such high temperatures makes device fabrication difficult in some instances, for example when other device components are adversely affected by the elevated temperatures. It would therefore be useful to provide absorber layers capable of being formed at lower temperatures.

One means of achieving lower processing temperatures might be to modify the composition of the chalcopyrite film. For example, it is known that replacing the Cu with Ag results in a chalcopyrite with a lower melting point. Unfortunately, literature references indicate that devices employing such chalcopyrite absorber layers show markedly inferior performance. For example, over a wide range of Ag/(In+Ga) and Ga/(In+Ga) compositions, the best device reported by Nakada exhibited a photovoltaic conversion efficiency of only 10.2%. (Nakada et al., Mater. Res. Soc. Symp. Proc. 865 2005 p. F11.1.1.) In contrast, Cu(InGa)Se₂ devices are known that exhibit a photovoltaic conversion efficiency of 19.9%, nearly twice as high. (Repins, I. et al., Prog. Photovolt.: Res. Appl. 16 (3) 2008, p. 235) In view of such poor device performance, there would appear to be little promise in using Ag instead of Cu in chalcopyrite-based absorber layers.

### SUMMARY OF THE INVENTION

In one aspect, the invention provides a film having a composition Ag_{w}Cu_{1-w}InᵣGaₓK_{y}Se_{2(1-z)}Q_{2z}; wherein K is Al or Tl or a combination of these; Q is S or Te or a combination of these; w is in a range from 0.01 to 0.75; x is in a range from 0.1 to 0.8; and r, y and z are each independently in a range from 0 to 1, provided that r+x+y=1.

In another aspect, the invention provides a method of making a photovoltaic device. The method includes depositing onto a substrate components in amounts sufficient to provide a chalcopyrite film of composition Ag₂CU_{1-w}InᵣGaₓK_{y}Se_{2(1-z)}Q_{2z}; wherein K is Al or Tl or a combination of these; Q is S or Te or a combination of these; w is in a range from 0.01 to 0.75; x is in a range from 0.1 to 0.8; and r, y and z are each independently in a range from 0 to 1, provided that r+x+y=1;

wherein the method is performed under temperature conditions not exceeding 500° C.

### BRIEF DESCRIPTION OF THE DRAWINGS

FIG. 1 shows a plot of external quantum efficiency measurements taken on a prior art CuInSe₂-based alloy device.

FIG. 2 shows a plot of external quantum efficiency measurements taken on a device according to the invention, similar to that of FIG. 1 but including Ag in the CuInSe₂-based alloy.

FIG. 3 is a plot showing improved spectral response of a Ag_{0.3}Cu_{0.7}Ga_{0.7}In_{0.3}Se₂ absorber layer according to the invention compared with a CuGa_{0.7}In_{0.3}Se₂ absorber layer.

FIG. 4 is an SEM image of a non-Ag-containing control absorber layer.

FIG. 5 is an SEM image of an Ag-containing absorber layer according to the invention.

FIG. 6 shows V_{OC} results for a device employing a prior art absorber layer containing no Ag and for four devices employing Ag-containing absorber layers according to the invention.

FIG. 7 shows efficiency results for the devices of FIG. 6.

FIG. 8 shows fill factor results for the devices of FIG. 6.

FIG. 9 shows J_{SC} results for the devices of FIG. 6.

FIG. 10 shows a plot of quantum efficiency as a function of wavelength for three of the devices of FIG. 6.

### DETAILED DESCRIPTION OF THE INVENTION

### Composition of the Layer

Chalcopyrite films according to the invention have a composition Ag₂Cu_{1-w}InᵣGaₓK_{y}Se_{2(1-z)}Q_{2z} wherein K is Al or Tl or a combination of these; Q is S or Te or a combination of these; w is in a range from 0.01 to 0.75; x is in a range from 0.1 to 0.8; and r, y and z are each independently in a range from 0 to 1, provided that r+x+y=1. Typically, w is in a range from 0.01 to 0.5, or 0.05 to 0.3, and most typically in a range from 0.1 to 0.2. In most cases, x is in a range from 0.15 to 0.5. Typically, z is in a range from 0 to 0.5, and in some cases it is in a range from 0.1 to 0.5. In some embodiments, the film comprises substantially only a single (112) phase. As is known to those skilled in the art, the composition description above is illustrative of the general stoichiometry needed to form a chalcopyrite, but it is not mathematically exact in that in practice. Chalcopyrite compositions may deviate somewhat from the perfect 1:1:2 mole ratio of Group I/Group III/Group VI₂ elements implied by the above formula. In practice, it is particularly true that the moles of group I atoms (Ag and Cu) indicated by the sum of r+x+y may exhibit a limited deviation from unity. In some situations, the sum may be as low as 0.9, or 0.8, or even as low as 0.7.

### Forming the Absorber Layer

In general, essentially any multi-step deposition/reaction/annealing process incorporating all of the desired elements may be used to produce absorber layers according to the invention. A wide variety of such techniques are known to those skilled in the art, and all may be suitable for the fabrication of absorber layers according to the invention. These techniques include, but are not limited to:
1) Deposition by gas, vacuum, or vapor phase techniques (vacuum evaporation, sputtering, vapor transport, etc.) of the constituent elements either in sequence or the simultaneous deposition of two or more elements, or any combination thereof.
2) Annealing or reaction of precursor films, where the “precursor” may consist of any combination of single or multiple phases of the constituent elements or compounds or alloys of two or more of the constituent elements, and the annealing or reaction may be conducted in an inert or Se- or S-containing atmosphere.
3) Sintering of micro- or nano-scale CuIn₁₋ₓGaₓSe_{2(1-y)}S_{2y} or precursor particles that have been deposited as a film, for example by suspension in solvent followed by coating and drying, onto the substrate in either inert or Se- or S-containing atmosphere.

In some embodiments, the method of making the film is performed under temperature conditions not exceeding 500° C., or not above 450° C., and in some cases the temperature does not exceed 425° C.

In some embodiments, the method comprises depositing onto a back contact of the substrate one or more films of elemental Ag, Tl, or Te, or oxides, sulfides, selenides, or tellurides of any of these. Subsequently one or more of Cu, In, Ga, Al, Se, or S is deposited. Optionally, one or more of Ag, Tl, or Te may also be deposited. This film may then be optionally be further processed if necessary at a further elevated temperature in an inert or O-, S-, Se-, or Te-containing atmosphere to form the chalcopyrite film.

In some embodiments, the method of making the film comprises depositing one or more films of elemental Ag, Cu, In, Ga, Tl, Al, Te, or alloys thereof, or oxides, sulfides, selenides, or tellurides of any of these via sputter deposition or via reactive sputter deposition in an oxygen-, sulfur-, selenium-, or tellurium-containing atmosphere.

Sputtering targets used in forming the back contact and Ag-, Tl-, or Te-containing layers may be provided in the same deposition chamber, and the substrate is translated to first be coated by the back contact, and then coated by the Ag-, Tl-, or Te-containing layer. Linear translation may be used in some cases.

The method may instead comprise the deposition and annealing, reaction, or sintering of a particulate chalcopyrite, or precursor particles in a vacuum, inert, or S-, Se-, or Te-containing atmosphere. Ag, Tl, or Te may be present in the pre-processed particulate films either in elemental form or as compounds.

Alternatively, Ag, Tl, or Te may be incorporated into the I-III-VI₂ absorber layer by simultaneous or sequential co-evaporation with Cu, In, Ga, Al, Se, or S.

In some embodiments, Tl or its sulfides, selenides, or tellurides are delivered to the substrate by thermal evaporation of TlS, Tl₂Se, Tl₂Te, or other Tl sulfides, selenides, or tellurides.

In another embodiment, an Ag film may be sputtered onto the back contact, followed by the formation of the remainder of the absorber layer by sequential or co-evaporation of Cu, Ga, In, Se, and optionally additional Ag, to form a resultant (AgCu)(InGa)Se₂ absorber layer.

In other embodiments, Ag, Tl, or Te are incorporated into a precursor film or films before annealing in a vacuum or inert atmosphere, or reaction in an S-, Se-, or Te-containing atmosphere to form the resultant I-III-VI₂ absorber layer.

In yet other embodiments, Ag, Tl, or Te are incorporated into the I-III-VI₂ absorber layer by deposition onto a film containing Cu, In, Ga, Al, Se, or S, and optionally Ag, Tl, or Te, and then heating in an inert, vacuum, or S-, Se-, or Te-containing atmosphere.

The method may also comprise sequentially co-evaporating Ag, Cu, In, Ga, and Se onto a heated substrate to form the chalcopyrite film. Or, it may involve depositing one or more layers of Ag, Cu, In, Ga, and optionally Se, or alloys or oxides, sulfides, or selenides thereof, and subsequently processing the film at a further elevated temperature in an inert, O-, S-, or Se-containing atmosphere to form the chalcopyrite film. Alternatively, the method may include depositing a particulate film comprising Ag, Cu, Tl, In, Ga, O, S, Se, or Te, or a combination thereof, or alloys or oxides, sulfides, selenides, or tellurides thereof, and subsequently processing the film at a further elevated temperature to form the chalcopyrite film.

Suitable substrates upon which to dispose the absorber layer films of this invention include any known in the art. Specific examples include metal films, glasses (including soda-lime glass), and self-supporting polymer films. The polymer films may for example be polyimides, liquid crystal polymers, or rigid-rod polymers. A typical film thickness may be about 50 μm to about 125 μm, although any thickness can be used.

The term “processing” as used herein refers to the sequence of steps used to form a film according to the invention, including but not limited to the techniques listed above.

### EXAMPLES

### Example 1

A soda-lime glass substrate was sputtered with Mo to form a 700 nm Mo film to serve as the back contact. A 92 nm Ag film was deposited by evaporation directly onto the Mo back contact. Cu, In, Ga, and Se were then co-evaporated onto this structure at a substrate temperature of 525° C. to create a resultant homogenous CU_{1-w}Ag_{w}In₁₋ₓGaₓSe₂ film with thickness 2 μm, and atomic ratios Ag/(Ag+Cu)=0.3, Ga/(Ga+In)=0.7, and (Ag+Cu)/(Ga+In)=0.85. A control film was also produced, employing a stoichiometrically equivalent 64 nm Cu film in place of the 92 nm Ag film. These absorber layer films were then used in the fabrication of photovoltaic devices by chemical bath deposition of 50 nm CdS, followed by sputter deposition of a 200 nm ZnO:ITO (indium tin oxide) window layer, followed by e-beam deposition of a Ni—Al grid structure. Photovoltaic device performance of the Ag-containing and non-Ag-containing devices is shown in Table I.

TABLE I
Comparison of photovoltaic device properties between Ag-
and non-Ag-containing absorber films. (2 samples per
absorber composition, 6 devices per sample, 12 devices
total per absorber composition. Notation: mean ± 1σ)

| Nominal absorber | V_{OC} | J_{SC} | FF | Eff. |
|---|---|---|---|---|
| composition | V | mA/cm² | % | % |
| Ag_{0.3}Cu_{0.7}Ga_{0.7}In_{0.3}Se₂ | 0.789 ± | 20.8 ± | 64.4 ± | 10.6 ± |
| | 0.005 | 1.3 | 1.9 | 0.8 |
| CuGa_{0.7}In_{0.3}Se₂ | 0.790 ± | 16.8 ± | 71.4 ± | 9.0 ± |
| | 0.009 | 1.4 | 1.0 | 2.0 |

V_{OC} = open-circuit voltage
J_{SC} = short-circuit current density
FF = fill factor = (max. power delivered by device)/(J_{SC} × V_{OC})
Eff. = photovoltaic energy conversion efficiency

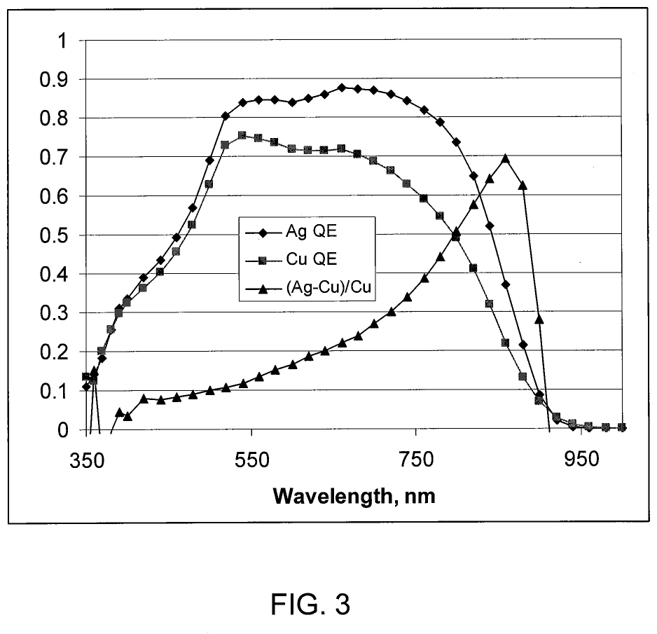

A further performance improvement achieved by an Ag-containing film vs. a non-Ag-containing film is shown in FIG. 3, in which an Ag-containing device according to the invention shows significantly improved current collection (which correlates to quantum efficiency, the parameter plotted on the Y-axis) compared with that of the non-Ag-containing film, especially near the high-wavelength band edge. FIG. 3 shows improved spectral response of the Ag_{0.3}Cu_{0.7}Ga_{0.7}In_{0.3}Se₂ absorber layer compared with CuGa_{0.7}In_{0.3}Seₑ. The curve labeled “(Ag—Cu)/Cu” shows the fractional enhancement in current collection obtained by the incorporation of Ag, demonstrating significant improvement at the high-wavelength band edge. In some embodiments of the invention, the device has a quantum efficiency at 860 nm that is at least 20% greater than that of an equivalent device employing an equivalent film that contains no Ag. In some embodiments, the improvement is at least 30%, 40%, 50%, or 60%. In the case shown in FIG. 3, the improvement was about 70%.

Based on the findings of the present invention, it is expected that addition of Tl or Te will also in some cases improve the quantum efficiency of the absorber layer.

### Example 2

Example 2 demonstrates the significantly enhanced annealing properties of I-III-VI₂ films incorporating Ag according to the invention. Cu, In, and Se were evaporated onto two types of samples at a substrate temperature of 525° C. over a 44 minute deposition time:
1) 1235 Å Ag on a substrate consisting of 0.7 μm Mo on soda-lime glass
2) A control sample consisting of 850 Å Cu (stoichiometrically equivalent to 1235 Å Ag) on 0.7 μm Mo on soda-lime glass

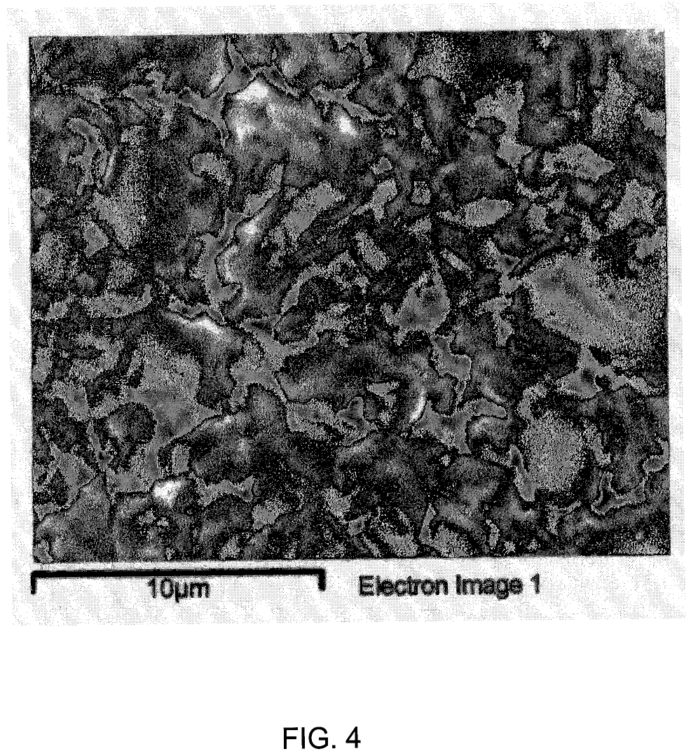

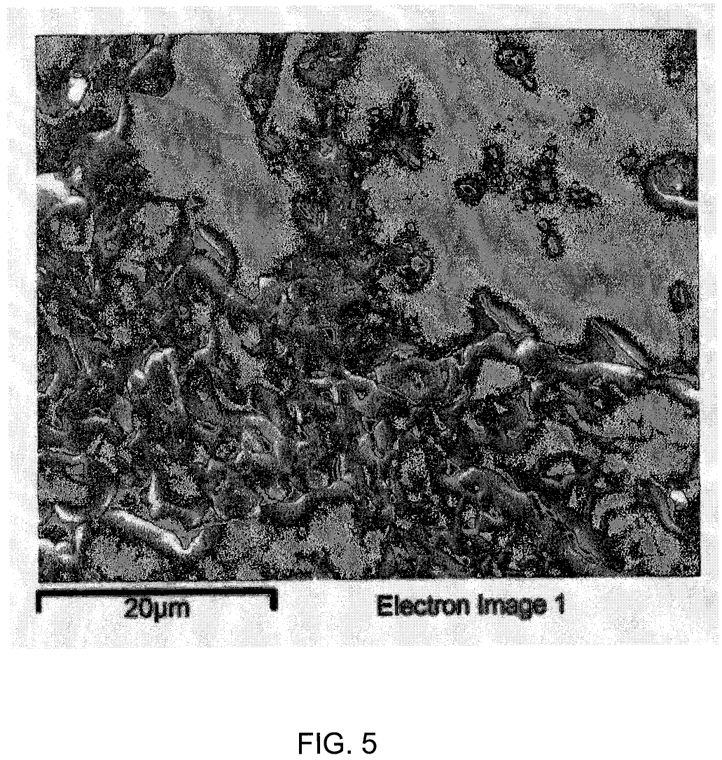

The deposition rates of the Cu, In, and Se were such that the final film thickness of the (AgCu)InSe₂ sample was approximately 2 μm with at Ag/(Ag+Cu) composition ratio of 0.57, and an (Ag+Cu)/In ratio of 0.96. The (I+III)/Se ratio was 1.00, indicating the sample was fully selenized. The Cu/In composition ratio of the CuInSe₂ control sample was 0.86. FIG. 4 shows an SEM image of the Cu control sample, indicating a maximum apparent CuInSe₂ grain size of about 5 μm. FIG. 5 shows an SEM image of the Ag-containing sample, indicating an apparent (AgCu)InSe₂ grain in excess of 40 μm occupying the upper half of the image. As known to those of skill in the art, such a large grain size indicates a very high degree of annealing and relaxation in the film.

Indeed, XRD analysis of the (AgCu)InSe₂ revealed only an extremely sharp (112) peak, indicating a compositionally homogeneous, well-annealed film that was essentially completely (112) oriented. It is known to those skilled in the art, lowering the processing temperature of the Ag-containing film can be expected to reduce the grain size to more nearly match that of the non-Ag-containing film, while maintaining good annealing. The ability to effectively anneal the film at lower temperatures is of significant value, for reasons discussed herein.

### Example 3

Ag_{0.15}Cu_{0.85}Ga_{0.75}In_{0.25}Se₂ films were deposited at 400° C. and 525° C. using the method described in the Example 1. Additionally, a Cu control sample (CuGa_{0.75}In_{0.25}Se₂) was included in the deposition at 525° C. The best Ag-containing devices in this series showed efficiencies of 10.3% and 12.4% at 400° C. and 525° C., respectively. Meanwhile, the best Cu control device was 11.5%, approximately midway between the high- and low-temperature Ag-containing devices. This result indicates that Ag-containing devices deposited at a temperature less than 550° C. but greater than 400° C. would be capable of matching the device performance of a Cu-only device deposited at 525° C.

### Example 4

(AgCu)(InGa)Se₂ films with Ag/(Ag+Cu)=0.12, Ga/(Ga+ln)=0.32, and (Ag+Cu)/(Ga+In)=0.89 were deposited by elemental co-evaporation onto Ag₂Se precursor films at a substrate temperature of 425° C. in the amounts stoichiometrically required for formation of a chalcopyrite phase, the presence of which was confirmed by XRD. Cu₂Se control samples were also present in the co-evaporation deposition. Devices fabricated from the Ag-containing samples exhibited an average photovoltaic conversion efficiency of 12.3%, while those of the Cu(InGa)Se₂ control samples exhibited an average efficiency of only 9.3%. Furthermore, the yield of non-shunted devices was 94% for the Ag-containing devices and only 43% for the Cu-only devices.

The Ag and Cu precursor films were deposited by evaporation onto Mo/SL (soda-lime glass) substrates at thicknesses of 440 Å and 305 Å, respectively. The Ag and Cu films were selenized at 400° C. in 0.35% H₂Se/Ar for 30 minutes to form Ag₂Se and Cu₂Se films, respectively. The purpose of this step was to remove oxidation from the films and to prevent further oxidation.

The selenized samples (four each of Ag—Se/Mo/SL and Cu—Se/Mo/SL) were then loaded into a co-evaporation deposition system in which Cu, In, Ga, and Se were evaporated onto the samples. The samples were maintained at a temperature of 425° C. during the 60-minute deposition. The resultant chalcopyrite films were 2 μm thick.

Devices were fabricated from the chalcopyrite films using a SL/Mo/chalcopyrite/CdS/ZnO:ITO/Ni—Al grid device structure and tested under 100 mW/cm² AM1.5 illumination. Shunted devices were not evaluated further.

The average (AgCu)(InGa)Se₂ device efficiency was 12.3% with a range of 10.8% to 14.0%. The average Cu(InGa)Se₂ device efficiency was 9.3% with a range of 8.4% to 10.3%. The primary factor in the improved device performance was the improved current collection in the Ag-containing devices. The addition of Ag improved J_{SC} from below 25 mA/cm² for Cu-only devices to >30 mA/cm² for the Ag-containing devices.

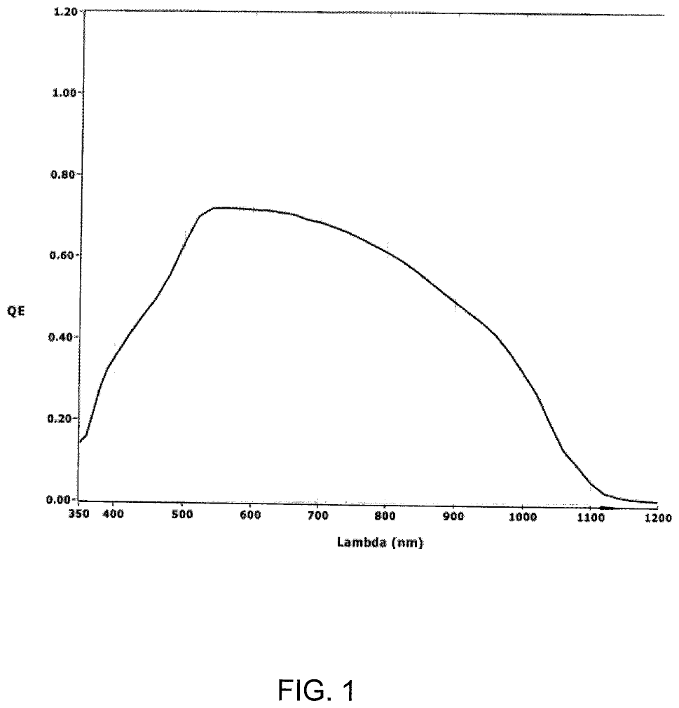

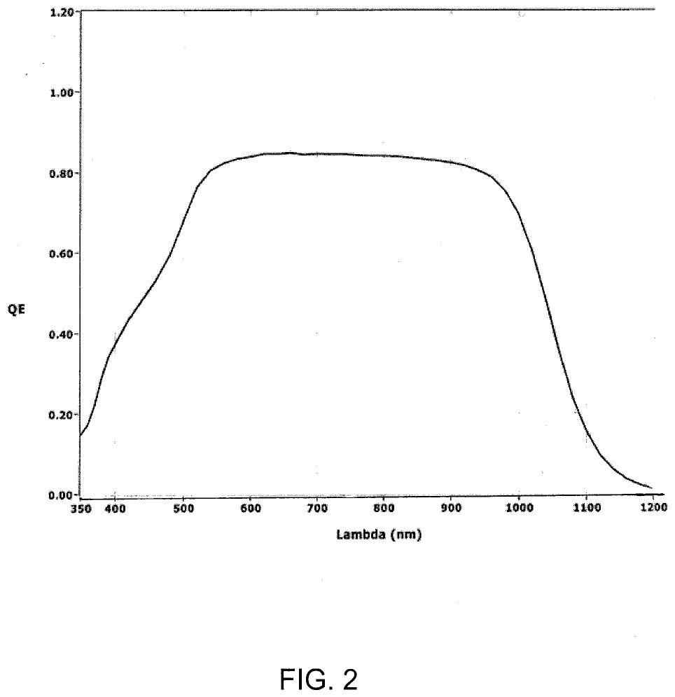

To verify the improved current collection, external quantum efficiency measurements were taken of selected Cu-only and Ag/Cu devices. These results are shown in FIG. 1 and FIG. 2, respectively. As can be seen, the Ag-containing device exhibited significantly improved current collection, particularly at long wavelengths, which translates into an improvement in device performance.

Additionally, the yield of the (AgCu)(InGa)Se₂ device was surprisingly high at 94%, while that of the Cu-only control device was only 43%. The magnitude of this improvement is difficult to explain by a monotonic temperature dependence, such as might for example be expected in the basic device performance properties (V_{oc}, J_{SC}, etc.). Such an improvement is of course highly significant from a potential manufacturing perspective.

### Example 5

Additional device performance data were obtained over an Ag/(Ag+Cu) range from 0 to 0.75 and a Ga/(In+Ga) range of about 0.27 to 1.0, using films grown at a substrate temperature of 525° C. using simultaneous evaporation of Ag, Cu, In, Ga, and Se. XRD analysis of the Ag/(Ag+Cu)=0.15, 0.30, and 0.5 series indicated the presence of a single phase by XRD. A sample with composition Ag/(Ag+Cu)=0.75 and Ga/(In+Ga)=0.53 exhibited the slight presence of a second phase observable as a slight shoulder on the chalcopyrite (112) peak. Devices were fabricated with the baseline structure SL/Mo/(AgCu)(InGa)Se₂/CdS/ZnO/ITO/Ni—Al grid with no anti-reflection layer. On each sample six cells with area 0.47 cm² were delineated by mechanical scribing.

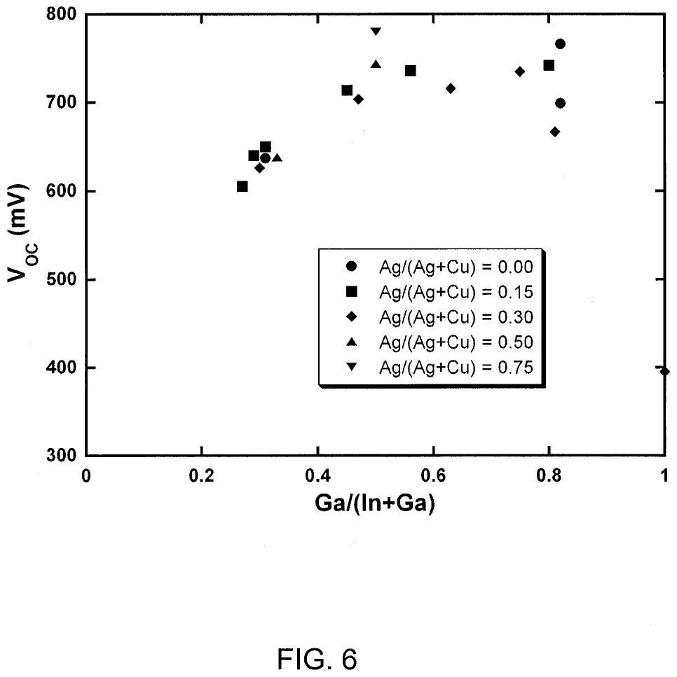

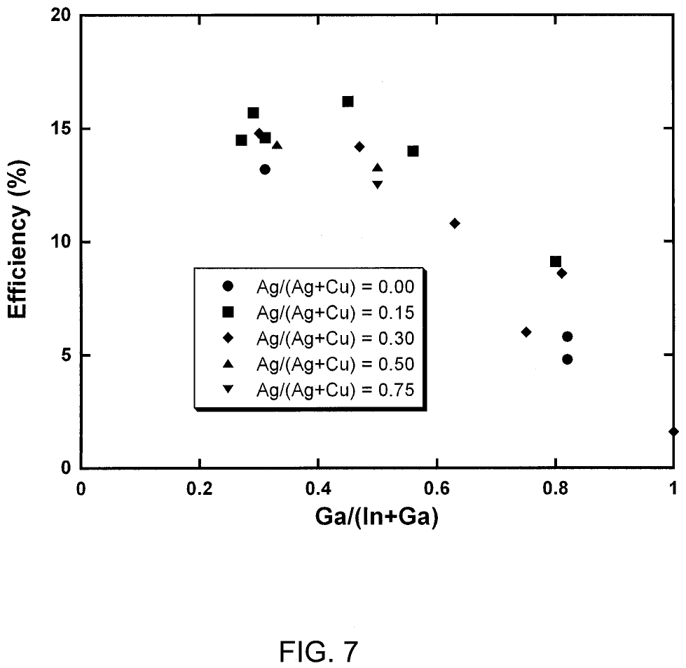

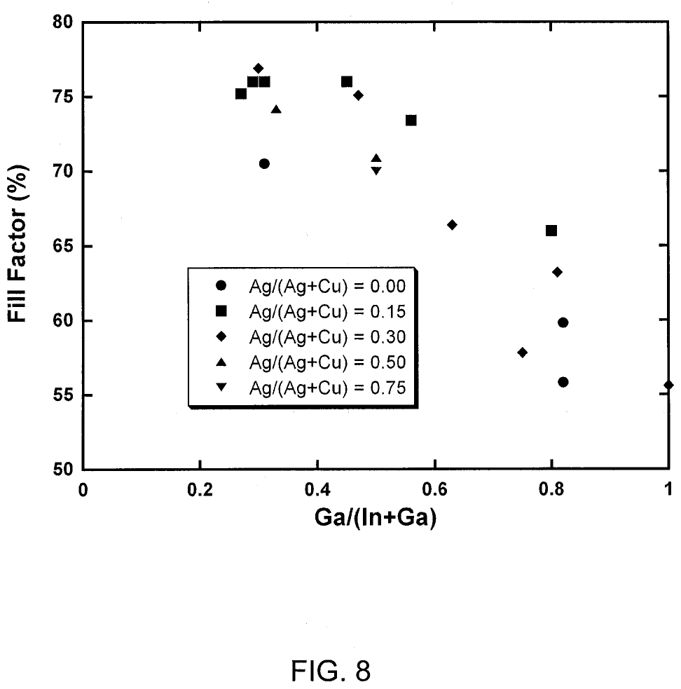

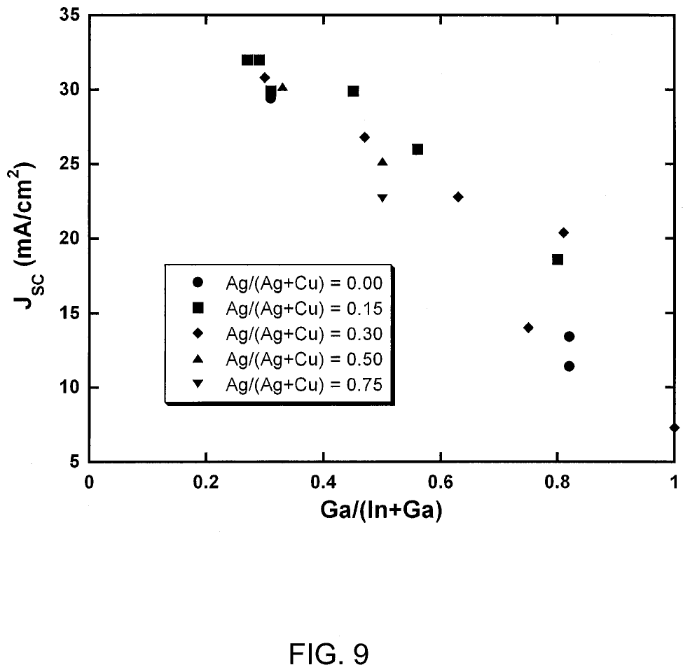

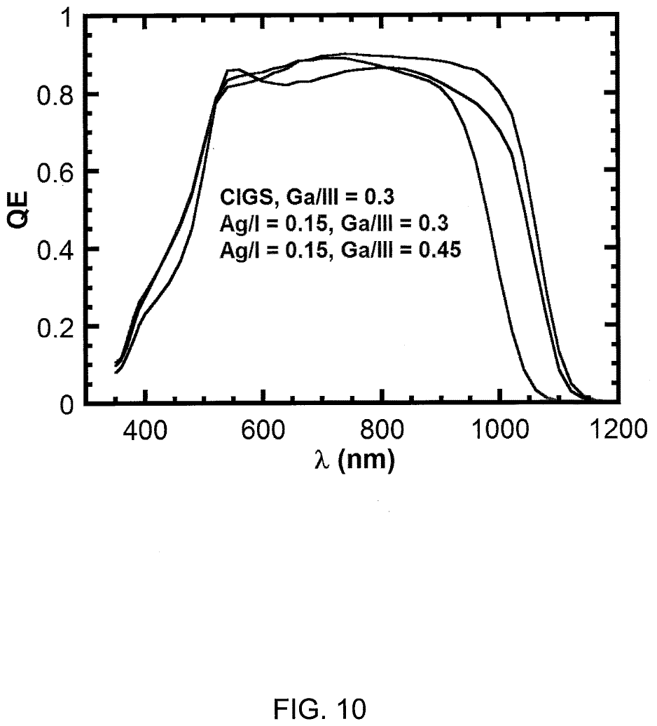

Test results are shown in FIGS. 6-10. Device performance was particularly good at Ag/(Ag+Cu) values of about 0.15 to 0.3. The presence of Ag is known in at least some systems to increase bandgap, and one might therefore have expected inclusion of Ag to increase V_{oc}. But surprisingly, the amount of Ag relative to Cu had little effect on V_{OC}, while the addition of Ag unexpectedly resulted in no evidence of a bandgap increase, as assessed by quantum efficiency device measurements as shown in FIG. 10. That is, in FIG. 10 the Ag/(Ag+Cu)=0.15 curve (labeled “Ag/I=0.15, Ga/III=0.3”) reveals a longer wavelength band edge than the CIGS (Cu/In/Ga/Se) curve, indicated a somewhat lower bandgap. However, and also surprisingly, the increase in current was disproportionately high compared to the slight decrease in bandgap. This is evidenced in FIG. 10 by the elevated plateau for the Ag/I=0.15, Ga/III=0.30 curve. In fact, an increase in J_{SC} can be seen. For example, see the data at approximately Ga/(Ga+ln)=0.30. As seen in FIG. 6, the voltage (V_{OC}) remained basically constant at about 630 mV with the addition of Ag, which was not expected, while the current (J_{SC}) increased (also not expected). J_{SC} values from three consecutive runs were measured, two with Ag/(Ag+Cu)=0.15 and one equivalent run with no Ag. The Ag-containing runs provided an additional 0.8 mA/cm² of current over the no-Ag run on average.

It should also be noted that fill factor values tended higher when Ag was present, for reasons that are at present not clear. Whatever the reason, higher fill factors are of value because they translate into proportionately higher photovoltaic conversion efficiencies.

The methods and compositions of the invention make possible improved performance and/or reduced processing temperature for I-III-VI₂-based photovoltaic devices. Typically, such benefits are achievable regardless of the specific type of processing method or sequence used.

Although the invention is illustrated and described herein with reference to specific embodiments, the invention is not intended to be limited to the details shown. Rather, various modifications may be made in the details within the scope and range of equivalents of the claims without departing from the invention.

What is claimed:

1. A method of making a photovoltaic device, comprising depositing onto a substrate components in amounts sufficient to provide a chalcopyrite film of composition Ag_{w}Cu_{1-w}InᵣGaₓK_{y}Se_{2(1-z)}Q_{2z}; wherein K is Al or Tl or a combination of these; Q is S or Te or a combination of these; w is in a range from 0.01 to 0.75; x is in a range from 0.1 to 0.8; and r, y and z are each independently in a range from 0 to 1, provided that r+x+y=1; wherein the method is performed under temperature conditions not exceeding 500° C.

2. The method of claim 1, wherein the temperature conditions do not exceed 450° C.

3. The method of claim 1, wherein the temperature conditions do not exceed 425° C.

4. The method of claim 1, wherein the substrate comprises a self-supporting polymer film.

5. The method of claim 1, wherein the substrate comprises a self-supporting polyimide, liquid crystal polymer, or rigid-rod polymer film.

6. The method of claim 1, wherein the substrate comprises soda-lime glass.

7. The method of claim 1, wherein the method comprises depositing onto a back contact of the substrate one or more films of elemental Ag, Tl, or Te, or oxides, sulfides, selenides, or tellurides of any of these; and subsequently depositing one or more of Cu, In, Ga, Al, Se, or S, and optionally one or more of Ag, Tl, or Te, and optionally further processing the film at a further elevated temperature in an inert or O-, S-, Se-, or Te-containing atmosphere to form the chalcopyrite film.

8. The method of claim 7, wherein the method comprises depositing the one or more films of elemental Ag, Tl, or Te, or oxides, sulfides, selenides, or tellurides of any of these via sputter deposition or via reactive sputter deposition in an oxygen-, sulfur-, selenium-, or tellurium-containing atmosphere.

9. The method of claim 8, wherein sputtering targets used in forming the back contact and Ag-, Tl-, or Te-containing layers are in the same deposition chamber, and wherein the substrate is first sputtered to form the back contact, and then coated by the Ag-, Tl-, or Te-containing layer.

10. The method of claim 7, comprising sputtering an Ag film onto the back contact and subsequently forming the remainder of the chalcopyrite film by sequentially co-evaporating Cu, Ga, In, Se, and optionally additional Ag.

11. The method of claim 1, wherein the method comprises sequentially co-evaporating Ag, Cu, In, Ga, and Se onto a heated substrate to form the chalcopyrite film.

12. The method of claim 1, wherein the method comprises depositing one or more layers of Ag, Cu, In, Ga, and optionally Se, or alloys or oxides, sulfides, or selenides thereof, and subsequently processing the film at a further elevated temperature in an inert, O-, S-, or Se-containing atmosphere to form the chalcopyrite film.

13. The method of claim 1, wherein the method comprises depositing a particulate film comprising Ag, Cu, Tl, In, Ga, O, S, Se, or Te, or a combination thereof, or alloys or oxides, sulfides, selenides, or tellurides thereof, and subsequently processing the film at a further elevated temperature to form the chalcopyrite film.

14. The method of claim 1, wherein w is in a range from 0.05 to 0.3.

15. The method of claim 1, wherein xis in a range from 0.15 to 0.5.

16. The method of claim 1, wherein K is Al.

17. The method of claim 1, wherein K is a combination of Al and Tl.

18. The method of claim 1, wherein Q is S.

19. The method of claim 1, wherein Q is a combination of S and Te.

20. The method of claim 1, wherein the film comprises substantially only a single chalcopyrite phase.
